(19) United States
(12) Patent Application Publication
(10) Pub. No.: US 2024/0379879 A1
(43) Pub. Date: Nov. 14, 2024

(54) SUPER FLASH AND METHOD FOR MANUFACTURING SAME

(71) Applicant: Shanghai Huali Integrated Circuit Corporation, Shanghai (CN)

(72) Inventors: Caiyun CHEN, Shanghai (CN); Zhen GU, Shanghai (CN); Lei ZHANG, Shanghai (CN); Chao CHEN, Shanghai (CN); Haoyu CHEN, Shanghai (CN)

(73) Assignee: Shanghai Huali Integrated Circuit Corporation, Shanghai (CN)

(21) Appl. No.: 18/612,961

(22) Filed: Mar. 21, 2024

(30) Foreign Application Priority Data
May 12, 2023 (CN) 202310538578.1

(51) Int. Cl. H01L 29/788; H01L 21/28; H01L 29/423; H01L 29/66

(52) U.S. Cl. CPC H01L 29/7883; H01L 29/40114; H01L 29/42328; H01L 29/66825

(57) ABSTRACT

The present application discloses a super flash, wherein a device cell includes a first gate trench at the top of a source region, a first spacer structure is formed on a side surface of the first gate trench in a self-aligned manner, and the first spacer structure is formed by means of self-aligned etch of a stack layer of a first tunneling dielectric layer, a floating gate, and a second oxide layer. The material of the floating gate comprises a TiN layer. A second spacer structure is formed on a second side surface of the first spacer structure in a self-aligned manner, and the second spacer structure is formed by means of self-aligned etch of a stack layer of a third silicon nitride layer, a fourth oxide layer, and a fifth silicon nitride layer. The present application further discloses a method for manufacturing a super flash.

### CROSS-REFERENCES TO RELATED APPLICATIONS

This application claims the priority to Chinese patent application No. CN 202310538578.1, filed on May 12, 2023, and entitled “SUPER FLASH AND METHOD FOR MANUFACTURING SAME”, the disclosure of which is incorporated herein by reference in entirety.

### TECHNICAL FIELD

The present application relates to a method for manufacturing a semiconductor integrated circuit, and in particular to a super flash (SF). The present application also relates to a method for manufacturing a super flash.

### BACKGROUND

For a flash memory of an SF 2.0 structure, erase and write efficiencies may be increased significantly and an operating voltage may be reduced, using an write operation with a horizontal electric field and an erase operation with tip SiN no-voltage coupling, The new structure allows for an increase in a nesting window of an erase gate (EG) for a floating gate (FG) and better tip control, and better endurance performance is expectable. The cell area is only 60% of that of an SF in the same generation, and the cost may be expected as being reduced greatly.

FIG. 1 is a schematic structural diagram of an existing super flash. The existing super flash includes:
a first gate trench 103 formed at the top of a source region 102, with a bottom surface of the first gate trench 103 being lower than a top surface of a semiconductor substrate 101 and a top surface of the first gate trench 103 being higher than a top surface of the semiconductor substrate 101.

Typically, the semiconductor substrate 101 includes a silicon substrate.

The source region 102 is formed in a surface region of the semiconductor substrate 101 at the bottom of the first gate trench 103.

Typically, the source regions 102 of memory cells of different super flashes are connected together and form a source line (SL) in a direction perpendicular to a paper direction corresponding to a section in FIG. 1.

A floating gate 105 and a control gate 107 are formed in the first gate trench 103.

The control gate 107 is typically a tungsten gate. The control gate 107 is in direct contact with the source region 102 at the bottom thereof.

An oxide layer 104 is formed between a first side surface of the floating gate 105 and side and bottom surfaces of the first gate trench 103. The oxide layer 104 is an HTO oxide layer.

An oxide layer 106 is formed between a second side surface of the floating gate 105 and a side surface of the control gate 107. The oxide layer 106 is typically formed by a stack of an atomic layer deposition (ALD) oxide layer and a high temperature oxide (HTO) oxide layer, with the ALD oxide layer being an oxide layer formed by an ALD process, and the HTO oxide layer being an oxide layer formed by an HTO process.

The floating gate 105 is made of a TiN layer; and the top of the floating gate 105 is higher than a top surface of the control gate 107.

Two word line gates 108 are symmetrically disposed on the semiconductor substrate 101 at both sides of the first gate trench 103, with each of the word line gates 108 being isolated from the semiconductor substrate 101 by a first gate dielectric layer (not shown) therebetween.

The side surface of the first gate trench 103 is isolated from a second side surface of the word line gate 108 by a dielectric layer 109 therebetween, and a first inter-gate dielectric layer is formed by a stack of the dielectric layer 109 and the oxide layer 104.

An erase gate 113 is formed at the top of the first gate trench 103, and the erase gate 113 covers a region larger than a formation region of the first gate trench 103. The erase gate 113 is isolated from the first inter-gate dielectric layer at the bottom thereof and the floating gate 105 is isolated from the oxide layer 106, by a second inter-gate dielectric layer 112 therebetween.

Typically, the dielectric layer 109 and the second inter-gate dielectric layer 112 are both oxide layers. Therefore, images corresponding to the dielectric layer 109, the second inter-gate dielectric layer 112, the oxide layer 104, and the oxide layer 106 in FIG. 1 are all filled with identical dots.

A drain region 111 is formed in a surface region of the semiconductor substrate 101 on a first side surface of the word line gate 108 in a self-aligned manner. Typically, a spacer (not shown) is also formed on the first side surface of the word line gate 108, and the drain region 111 is self-aligned with the spacer on the first side surface of the word line gate 108. A lightly doped drain (LDD) region 110 is also formed at a side of the drain region 111, with the lightly doped drain region 110 being self-aligned with the first side surface of the word line gate 108.

Typically, the word line gate 108 is a polysilicon gate or a metal gate; and the erase gate 113 is a polysilicon gate or a metal gate.

FIGS. 2A to 2B are schematic diagrams of device structures in various substeps of forming a floating gate in an existing method for manufacturing a super flash. The existing method for manufacturing a super flash includes the following steps:
Step 1. Referring to FIG. 1, the first gate trench 103 is formed in formation regions of the floating gate 105 and the control gate 107, the first gate trench 103 being located at the top of a formation region of the source region 102, with the bottom surface of the first gate trench 103 being lower than the top surface of the semiconductor substrate 101 and the top surface of the first gate trench 103 being higher than the top surface of the semiconductor substrate 101.
Step 2. The source region 102 is formed in the surface region of the semiconductor substrate 101 at the bottom of the first gate trench 103.
Step 3. The floating gate 105 is formed, including the following substeps:
Step 31. Referring to FIG. 2A, an oxide layer 104a is formed on the side and bottom surfaces of the first gate trench 103.

In the existing method, the oxide layer 104a is formed using an HTO oxidation process.
Step 32. Referring to FIG. 2A, a TiN layer 105a of the floating gate 105 is formed on the surface of the oxide layer 104a.
Step 33. Referring to FIG. 2A, an oxide layer 106a is formed on the surface of the TiN layer 105a.

In the existing method, the oxide layer 106a is formed using an HTO oxidation process.
Step 34. Referring to FIG. 2B, blank etch is performed on the oxide layer 106a, the TiN layer 105a, and the oxide layer 104a, so that the oxide layer 106, the TiN layer, and the oxide layer 104 are retained on only the side surface of the first gate trench 103 and present a spacer structure. All the oxide layer 106a, the TiN layer 105a, and the oxide layer 104a that are on the bottom surface of the first gate trench 103 outside the spacer structure and that are outside the first gate trench 103 are removed; the floating gate 105 is composed of the retained TiN layer. In FIG. 2B, the etched oxide layer, the TiN layer, and the oxide layer are denoted by labels 106, 105, and 104 respectively.

FIGS. 3A to 3B are schematic diagrams of device structures in various substeps of forming a floating gate in an existing improved method for manufacturing a super flash. The existing improved method for manufacturing a super flash shown in FIGS. 3A to 3B differs from the existing improved method for manufacturing a super flash shown in FIGS. 2A to 2B in the following:

In step 33 of step 3, the formation of the oxide layer 106a is followed by a step of forming a silicon nitride layer 114a, the silicon nitride layer 114a serving as a coupling silicon nitride layer (coupling SiN), which is grown typically using an ALD process.

As such, the silicon nitride layer 114a is etched first in step 34, and then blank etch is performed on the oxide layer 106a, the TiN layer 105a, and the oxide layer 104a, thereby forming the silicon nitride layer 114, the oxide layer 106, the TiN layer, and the oxide layer 104, which are retained on only the side surface of the first gate trench 103 after the etch.

The TiN layer of the floating gate 105 are surrounded by oxygen elements and are prone to oxidization during the high temperature process, making the entire TiN layer serving as the floating gate 105 discontinuous, which imposes adverse impacts to the erase operation, e.g., a high erase voltage and a slow erase rate.

In the existing improved method for manufacturing a super flash corresponding to FIGS. 3A to 3B, the silicon nitride layer 114 is added to protect the TiN layer to a certain degree. However, results of an energy dispersive spectrometer (EDS) and a transmission electron microscope (TEM) show that a top region of the TiN layer of the floating gate 105 is still prone to oxidation under the impacts of the surrounding environment and process, resulting in a high erase voltage and a slow erase rate. EDS line scan is performed to analyze elemental contents of each region of the floating gate 105 shown in FIG. 3B.

It is found that the top region of the TiN layer of the floating gate 105 has a higher oxygen content than other regions, and a higher Ti/N ratio than bottom and middle portions. The top region of the TiN layer of the floating gate 105 is an erase region, and oxidation of the top region is likely to impose an adverse impact on the erase performance.

### BRIEF SUMMARY

According to some embodiments in this application, a device cell of the super flash provided by the present application is located in a storage region, and the device cell includes:

a first gate trench formed at the top of a source region, with a bottom surface of the first gate trench being lower than a top surface of a semiconductor substrate and a top surface of the first gate trench being higher than a top surface of the semiconductor substrate.

The source region is formed in a surface region of the semiconductor substrate at the bottom of the first gate trench.

A first spacer structure is formed on a side surface of the first gate trench in a self-aligned manner, the first spacer structure is formed by means of self-aligned etch of a first stack layer, the first stack layer is formed by a stack of a first tunneling dielectric layer, a floating gate, and a second oxide layer, the first tunneling dielectric layer is formed on side and bottom surfaces of the first gate trench, the floating gate is formed on a surface of the first tunneling dielectric layer, and the second oxide layer is formed on a surface of the floating gate.

The material of the floating gate includes a TiN layer.

A second side surface of the first spacer structure is formed by a stack of a second side surface of the second oxide layer and etched surfaces of the floating gate and the first tunneling dielectric layer at the bottom of the second side surface of the second oxide layer; the bottom surface of the first gate trench is exposed between the second side surfaces of the first spacer structure.

A second spacer structure is formed on the second side surface of the first spacer structure in a self-aligned manner, and the second spacer structure is formed by means of self-aligned etch of a second stack layer; the second stack layer is formed by a stack of a third silicon nitride layer, a fourth oxide layer, and a fifth silicon nitride layer; the third silicon nitride layer is formed on the second side surface of the first spacer structure and on the bottom surface of the first gate trench, the fourth oxide layer is formed on a surface of the third silicon nitride layer, and the fifth silicon nitride layer is formed on a surface of the fourth oxide layer.

The second side surface of the second spacer structure is formed by a stack of a second side surface of the fifth silicon nitride layer and etched surfaces of the fourth oxide layer and the third silicon nitride layer at the bottom of the second side surface of the fifth silicon nitride layer; the bottom surface of the first gate trench is exposed between the second side surfaces of the second spacer structure.

The second oxide layer is an ALD oxide layer.

The fourth oxide layer is an HTO oxide layer.

The third silicon nitride layer serves as a protective layer for the floating gate to prevent the TiN layer of the floating gate from being oxidized.

In some cases, a control gate fills the first gate trench between the second side surfaces of the second spacer structure, the control gate being in contact with the source region at the bottom thereof.

Two word line gates are symmetrically disposed on the semiconductor substrate at both sides of the first gate trench, with each of the word line gates being isolated from the semiconductor substrate by a first gate dielectric layer therebetween.

The side surface of the first gate trench is isolated from a second side surface of the word line gate by a sixth dielectric layer therebetween.

An erase gate is formed in a top region of the floating gate, and the erase gate is spaced apart from the floating gate by a second tunneling dielectric layer therebetween.

A drain region is formed in a surface region of the semiconductor substrate on a first side surface of the word line gate in a self-aligned manner.

In some cases, the first tunneling dielectric layer is an HTO oxide layer.

In some cases, the third silicon nitride layer is an ALD silicon nitride layer; and the fifth silicon nitride layer is an ALD silicon nitride layer.

In some cases, the thickness of the first tunneling dielectric layer is 40 Å to 200 Å.

The thickness of the second oxide layer is 20 Å to 30 Å.

The thickness of the third silicon nitride layer is 20 Å to 30 Å.

The thickness of the fourth oxide layer is 20 Å to 100 Å.

The thickness of the fifth silicon nitride layer is 30 Å to 60 Å.

In some cases, the thickness of the floating gate is 20 Å to 40 Å.

In order to solve the above problem, in the method for manufacturing a super flash provided by the present application, a device cell is located in a storage region, and steps of forming the device cell include:
step 1, forming a first gate trench, the first gate trench being located at the top of a formation region of a source region, with a bottom surface of the first gate trench being lower than a top surface of a semiconductor substrate and a top surface of the first gate trench being higher than a top surface of the semiconductor substrate;
step 2, forming the source region in a surface region of the semiconductor substrate at the bottom of the first gate trench;
step 3, forming a first spacer structure on a side surface of the first gate trench in a self-aligned manner, including the following substeps:
step 31, forming a first tunneling dielectric layer on the side and bottom surfaces of the first gate trench, forming a floating gate on a surface of the first tunneling dielectric layer, and forming a second oxide layer on a surface of the floating gate, wherein a first stack layer is formed by a stack of the first tunneling dielectric layer, the floating gate, and the second oxide layer; the first stack layer also extends to a surface outside the first gate trench;
the material of the floating gate includes a TiN layer;
the second oxide layer is an ALD oxide layer; and
step 32, sequentially etching the second oxide layer, the floating gate, and the first tunneling dielectric layer to form the first spacer structure on the side surface of the first gate trench in the self-aligned manner, wherein

a second side surface of the first spacer structure is formed by a stack of a second side surface of the second oxide layer and etched surfaces of the floating gate and the first tunneling dielectric layer at the bottom of the second side surface of the second oxide layer; the bottom surface of the first gate trench is exposed between the second side surfaces of the first spacer structure; and
step 4, forming a second spacer structure on the second side surface of the first spacer structure in a self-aligned manner, including the following substeps:
step 41, forming a third silicon nitride layer on the second side surface of the first spacer structure and on the bottom surface of the first gate trench, forming a fourth oxide layer on a surface of the third silicon nitride layer, and forming a fifth silicon nitride layer on a surface of the fourth oxide layer, wherein a second stack layer is formed by a stack of the third silicon nitride layer, the fourth oxide layer, and the fifth silicon nitride layer; the second stack layer also extends to a top surface of the first spacer structure and a surface outside the first gate trench;
the fourth oxide layer is an HTO oxide layer;
the third silicon nitride layer serves as a protective layer for the floating gate to prevent the TiN layer of the floating gate from being oxidized; and
step 42, sequentially etching the fifth silicon nitride layer, the fourth oxide layer, and the third silicon nitride layer to form the second spacer structure on the second side surface of the first spacer structure in the self-aligned manner, wherein
a second side surface of the second spacer structure is formed by a stack of a second side surface of the fifth silicon nitride layer and etched surfaces of the fourth oxide layer and the third silicon nitride layer at the bottom of the second side surface of the fifth silicon nitride layer; the bottom surface of the first gate trench is exposed between the second side surfaces of the second spacer structure.

In some cases, two word line gates are symmetrically disposed on the semiconductor substrate at both sides of the first gate trench in step 1, with each of the word line gates being isolated from the semiconductor substrate by a first gate dielectric layer therebetween.

The side surface of the first gate trench is isolated from a second side surface of the word line gate by a sixth dielectric layer therebetween.

After step 4, the method further includes: step 5, filling the first gate trench between the second side surfaces of the second spacer structure with a control gate, the control gate being in contact with the source region at the bottom thereof.

After step 5, the method further includes:
forming an erase gate and a second tunneling dielectric layer between the erase gate and the floating gate in a top region of the floating gate.

After forming a first side surface of the word line gate, the method further includes:
forming a drain region in a surface region of the semiconductor substrate on the first side surface of the word line gate in a self-aligned manner.

In some cases, the first tunneling dielectric layer is an HTO oxide layer that is grown by means of an HTO process.

In some cases, the third silicon nitride layer is an ALD silicon nitride layer that is grown by means of an ALD process; and the fifth silicon nitride layer is an ALD silicon nitride layer that is grown by means of an ALD process.

In some cases, the thickness of the first tunneling dielectric layer is 40 Å to 200 Å.

The thickness of the second oxide layer is 20 Å to 30 Å.

The thickness of the third silicon nitride layer is 20 Å to 30 Å.

The thickness of the fourth oxide layer is 20 Å to 100 Å.

The thickness of the fifth silicon nitride layer is 30 Å to 60 Å.

In some cases, a temperature of the HTO process for the first tunneling dielectric layer is 600° C. to 900° C.

In some cases, the TiN layer of the floating gate is formed by means of deposition using a PVD process.

In some cases, a temperature of the PVD process for the TiN layer of the floating gate is 400 degrees Celsius.

In some cases, the thickness of the floating gate is 20 Å to 40 Å.

In some cases, a non-storage region is further provided outside the storage region.

At the same time when forming the first gate trench, the method in step 1 further includes forming a second gate trench in the non-storage region, the second gate trench being located above a field oxide, and the field oxide being formed on the semiconductor substrate.

The first stack layer is also formed on an inner side surface of the second gate trench and on a surface outside the second gate trench in step 31.

Before performing an etch process for the first spacer structure, the method in step 32 further includes:
forming a first mask layer for covering the storage region and opening the non-storage region;
removing the entire first stack layer in the non-storage region using the first mask layer as a mask; and
etching off the first mask layer.

In some cases, a process of etching the TiN layer of the floating gate in the first stack layer in step 32 is wet etch, and a wet etch solution is a mixed cleaning solution of HF, H₂O₂, and H₂O.

In some cases, an etch process for the fifth silicon nitride layer, the fourth oxide layer, and the third silicon nitride layer in step 42 is an anisotropic dry etch process.

According to the present application, the third silicon nitride layer is disposed between the second oxide layer on the surface of the floating gate and the fourth oxide layer formed subsequently by the HTO oxide layer. The third silicon nitride layer may serve as a protective layer for the TiN layer of the floating gate to protect the TiN layer particularly during the HTO oxidation process for the fourth oxide layer and prevent the TiN layer from being oxidized, and in particular to prevent the top region of the TiN layer from being oxidized, which, in combination with a protection function provided by the fifth silicon nitride layer, may ultimately improve the structural continuity of the TiN layer of the floating gate and thereby improve the erase performance of the device.

### BRIEF DESCRIPTION OF THE DRAWINGS

The present application is further described in detail below in conjunction with the drawings and specific implementations:

FIG. 1 is a schematic structural diagram of an existing 38 super flash;

FIGS. 2A-2B are schematic diagrams of device structures in various substeps of forming a floating gate in an existing method for manufacturing a super flash;

FIGS. 3A-3B are schematic diagrams of device structures in various substeps of forming a floating gate in an existing improved method for manufacturing a super flash;

FIG. 4 is a schematic structural diagram of a super flash according to embodiments of the present application; and

FIGS. 5A-5G are schematic diagrams of device structures in various substeps of forming a floating gate in a method for manufacturing a super flash according to embodiments of the present application.

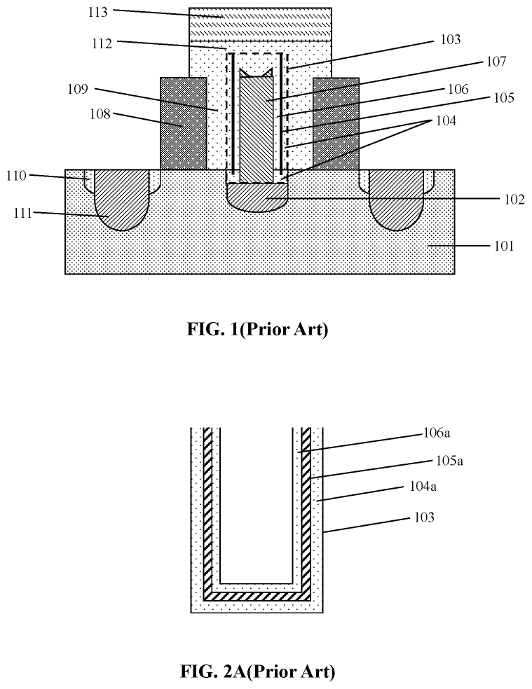

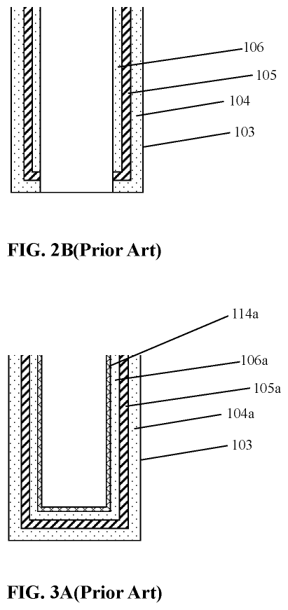

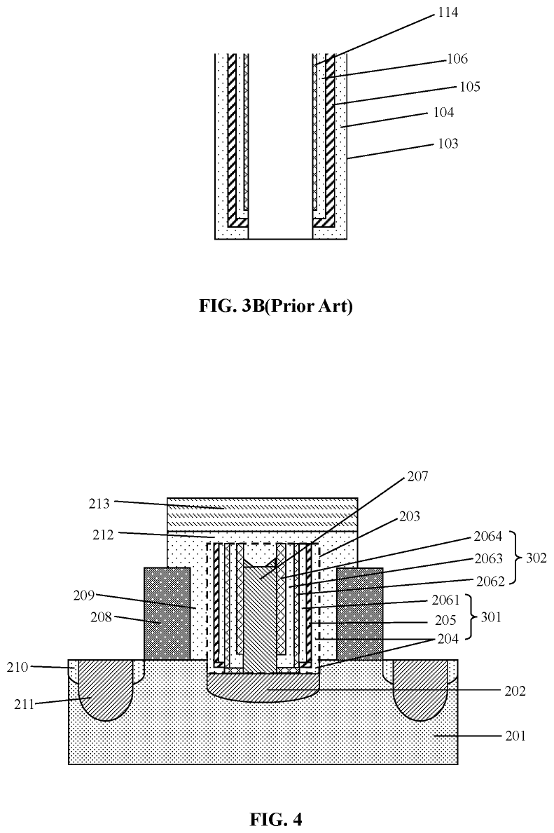

### DETAILED DESCRIPTION OF THE DISCLOSURE

FIG. 4 is a schematic structural diagram of a super flash according to embodiments of the present application. A device cell of the super flash according to the embodiments of the present application is located in a storage region 303, and the device cell includes:

a first gate trench 203 formed at the top of a source region 202, with a bottom surface of the first gate trench 203 being lower than a top surface of a semiconductor substrate 201 and a top surface of the first gate trench 203 being higher than a top surface of the semiconductor substrate 201.

The semiconductor substrate 201 includes a silicon substrate.

The source region 202 is formed in a surface region of the semiconductor substrate 201 at the bottom of the first gate trench 203.

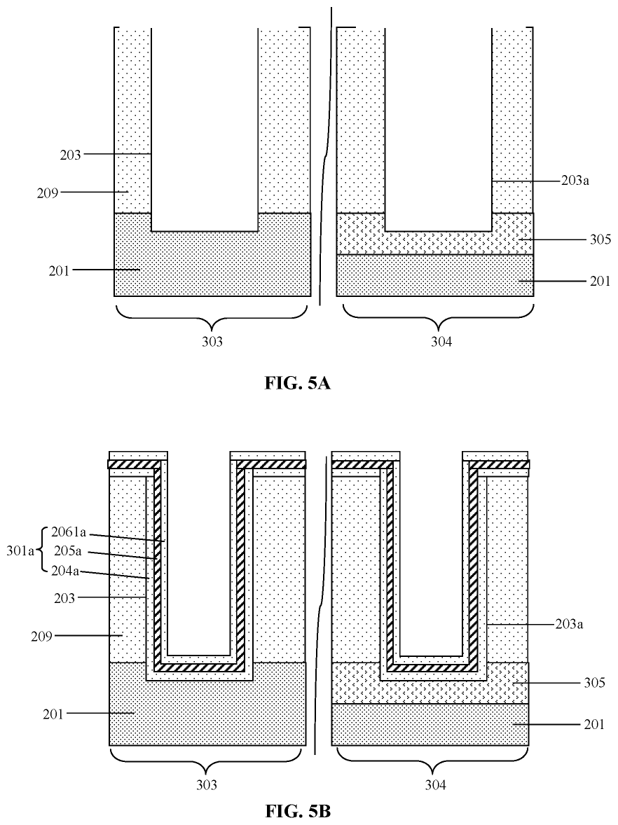

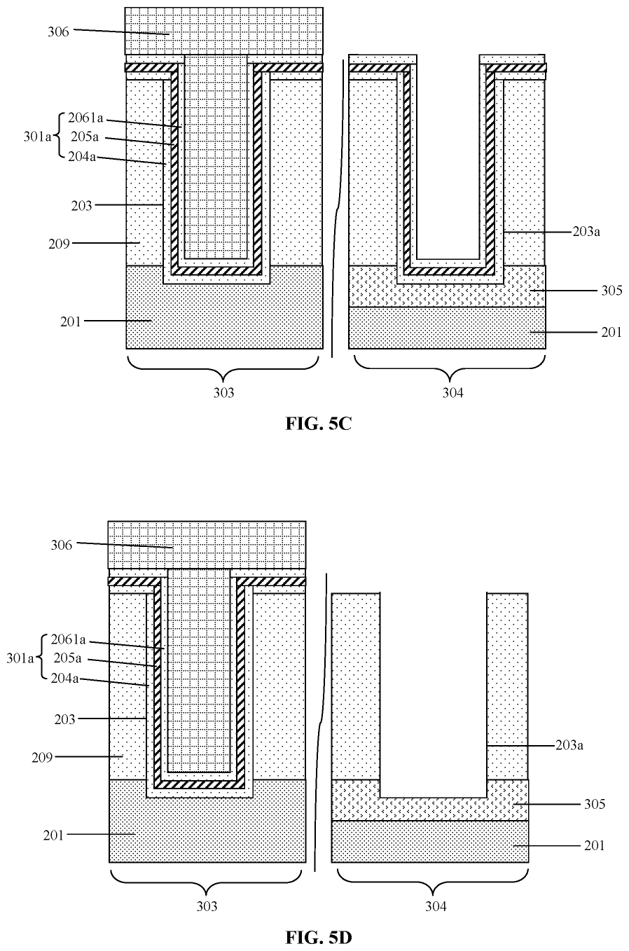

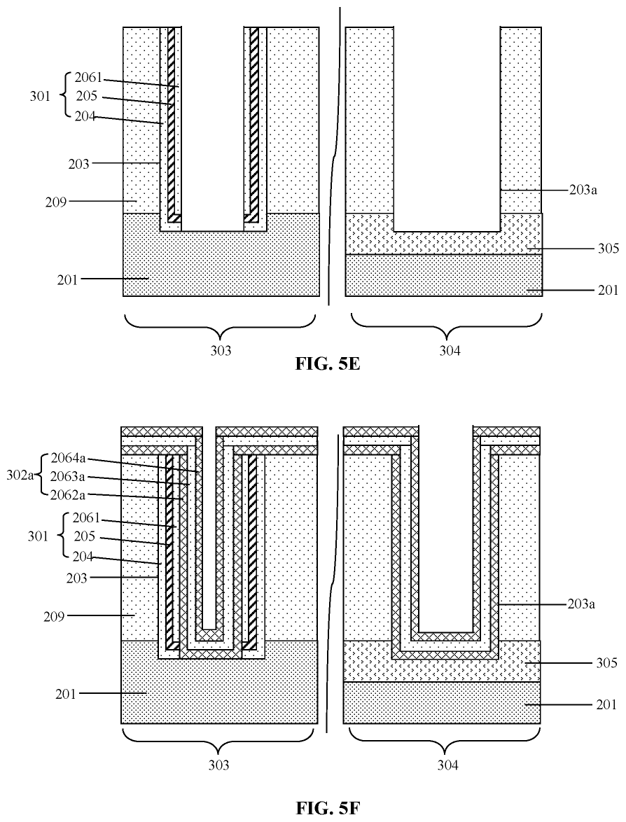

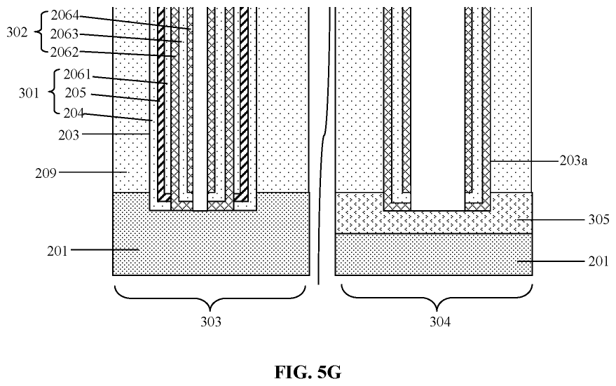

A first spacer structure 301 is formed on a side surface of the first gate trench 203 in a self-aligned manner, the first spacer structure 301 is formed by means of self-aligned etch of a first stack layer 301a. Reference is made to FIG. 5B for the structure of the first stack layer 301a. The first stack layer 301a is formed by a stack of a first tunneling dielectric layer 204a, a floating gate 205a, and a second oxide layer 2061a, the first tunneling dielectric layer 204a is formed on side and bottom surfaces of the first gate trench 203, the floating gate 205a is formed on a surface of the first tunneling dielectric layer 204a, and the second oxide layer 2061a is formed on a surface of the floating gate 205a. After the self-aligned etch, in the first spacer structure 301, the first tunneling dielectric layer is separately denoted by a label 204, the floating gate is separately denoted by a label 205, and the second oxide layer is separately denoted by a label 2061.

The material of the floating gate 205 includes a TiN layer.

A second side surface of the first spacer structure 301 is formed by a stack of a second side surface of the second oxide layer 2061 and etched surfaces of the floating gate 205 and the first tunneling dielectric layer 204 at the bottom of the second side surface of the second oxide layer 2061; the bottom surface of the first gate trench 203 is exposed between the second side surfaces of the first spacer structure 301.

A second spacer structure 302 is formed on the second side surface of the first spacer structure 301 in a self-aligned manner, and the second spacer structure 302 is formed by means of self-aligned etch of a second stack layer 302a. Reference is made to FIG. 5F for the structure of the second stack layer 302a. The second stack layer 302a is formed by a stack of a third silicon nitride layer 2062a, a fourth oxide layer 2063a, and a fifth silicon nitride layer 2064a; the third silicon nitride layer 2062a is formed on the second side surface of the first spacer structure 301 and on the bottom surface of the first gate trench 203, the fourth oxide layer 2063a is formed on a surface of the third silicon nitride layer 2062a, and the fifth silicon nitride layer 2064a is formed on a surface of the fourth oxide layer 2063a. After the self-aligned etch, in the second spacer structure 302, the third silicon nitride layer is separately denoted by a label 2062, the fourth oxide layer is separately denoted by a label 2063, and the fifth silicon nitride layer is separately denoted by a label 2064.

The second side surface of the second spacer structure 302 is formed by a stack of a second side surface of the fifth silicon nitride layer 2064 and etched surfaces of the fourth oxide layer 2063 and the third silicon nitride layer 2062 at the bottom of the second side surface of the fifth silicon nitride layer 2064; the bottom surface of the first gate trench 203 is exposed between the second side surfaces of the second spacer structure 302.

A control gate 207 fills the first gate trench 203 between the second side surfaces of the second spacer structure 302, and the control gate is in contact with the source region 202 at the bottom thereof.

In some embodiments, the control gate 207 is formed using a tungsten material.

The second oxide layer 2061 is an ALD oxide layer.

The fourth oxide layer 2063 is an HTO oxide layer.

The third silicon nitride layer 2062 serves as a protective layer for the floating gate 205 to prevent the TiN layer of the floating gate from being oxidized.

In the embodiments of the present application, two word line gates 208 are symmetrically disposed on the semiconductor substrate 201 at both sides of the first gate trench 203, with each of the word line gates 208 being isolated from the semiconductor substrate 201 by a first gate dielectric layer (not shown) therebetween.

The side surface of the first gate trench 203 is isolated from a second side surface of the word line gate 208 by a sixth dielectric layer 209 therebetween.

An erase gate 213 is formed in a top region of the floating gate 205, and the erase gate 213 is spaced apart from the floating gate 205 by a second tunneling dielectric layer 212 therebetween. During erase operation performed on the floating gate 205, charges stored in the floating gate 205 pass through the second tunneling dielectric layer 212 and enter the erase gate 213, thereby erasing the floating gate 205.

In the embodiments of the present application, the erase gate 213 covers the floating gates 205 on both side surfaces of the first gate trench 203 at the same time. The width of the erase gate 213 is typically set to be greater than the width of the first gate trench 203. The second tunneling dielectric layer 212 also serves as an inter-gate dielectric layer between the erase gate 213 and the word line gate 208 as well as the control gate 207 at the bottom thereof.

In the embodiments of the present application, the sixth dielectric layer 209, the second tunneling dielectric layer 212, and the first tunneling dielectric layer 204 are all oxide layers. Therefore, images corresponding to the sixth dielectric layer 209, the second tunneling dielectric layer 212, the first tunneling dielectric layer 204, the fourth oxide layer 2063, and the second oxide layer 2061 in FIG. 4 are all filled with identical dots.

A drain region 211 is formed in a surface region of the semiconductor substrate 201 on a first side surface of the word line gate 208 in a self-aligned manner. In some embodiments, a lightly doped drain region 210 is also formed in the surface region of the semiconductor substrate 201 on the first side surface of the word line gate 208.

In some embodiments, the first tunneling dielectric layer 204 is an HTO oxide layer. During programming performed on the floating gate 205, a channel region surface of a region covered by the word line gate 208 undergoes inversion to form a conductive channel, which causes conductivity between the drain region 211 and the source region 202, and hot carriers are formed in the vicinity of the source region 202 and pass through the first tunneling dielectric layer 204 to enter the floating gate 205.

The third silicon nitride layer 2062a is an ALD silicon nitride layer; and the fifth silicon nitride layer 2064a is an ALD silicon nitride layer. The TiN layer of the floating gate 205 is formed by means of deposition using a PVD process.

The thickness of the first tunneling dielectric layer 204a is 40 Å to 200 Å.

The thickness of the second oxide layer 2061a is 20 Å to 30 Å.

The thickness of the third silicon nitride layer 2062a is 20 Å to 30 Å.

The thickness of the fourth oxide layer 2063a is 20 Å to 100 Å.

The thickness of the fifth silicon nitride layer 2064a is 30 Å to 60 Å.

The thickness of the floating gate 205 is 20 Å to 40 Å.

According to the embodiments of the present application, the third silicon nitride layer 2062 is disposed between the second oxide layer 2061 on the surface of the floating gate 205 and the fourth oxide layer 2063 formed subsequently by the HTO oxide layer. The third silicon nitride layer 2062 may serve as a protective layer for the TiN layer of the floating gate 205 to protect the TiN layer particularly during the HTO oxidation process for the fourth oxide layer 2063 and prevent the TiN layer from being oxidized, and in particular to prevent the top region of the TiN layer from being oxidized, which, in combination with a protection function provided by the fifth silicon nitride layer 2064, may ultimately improve the structural continuity of the TiN layer of the floating gate 205 and thereby improve the erase performance of the device.

FIGS. 5A to 5G are schematic diagrams of device structures in various substeps of forming a floating gate 205 in a method for manufacturing a super flash according to embodiments of the present application. In the method for manufacturing a super flash according to the embodiments of the present application, a device cell is located in a storage region 303, and steps of forming the device cell include the following:
Step 1. Referring to FIG. 5A, a first gate trench 203 is formed, the first gate trench 203 being located at the top of a formation region of a source region 202, with a bottom surface of the first gate trench 203 being lower than a top surface of a semiconductor substrate 201 and a top surface of the first gate trench 203 being higher than a top surface of the semiconductor substrate 201.

The storage region 303 and a non-storage region 304 are both shown in FIG. 5A.

In the method according to the embodiments of the present application, further referring to FIG. 4, two word line gates 208 are symmetrically disposed on the semiconductor substrate 201 at both sides of the first gate trench 203, with each of the word line gates 208 being isolated from the semiconductor substrate 201 by a first gate dielectric layer therebetween. The word line gate 208 is not shown in FIG. 5A, and only a region between the word line gates 208 in the storage region 303 is shown in FIG. 5A.

The side surface of the first gate trench 203 is isolated from a second side surface of the word line gate 208 by a sixth dielectric layer 209 therebetween.
Step 2. The source region 202 is formed in a surface region of the semiconductor substrate 201 at the bottom of the first gate trench 203. Reference may be made to FIG. 4 for the source region 202.
Step 3. A first spacer structure 301 is formed on a side surface of the first gate trench 203 in a self-aligned manner, including the following substeps:
Step 31. Referring to FIG. 5B, a first tunneling dielectric layer 204a is formed on the side and bottom surfaces of the first gate trench 203, a floating gate 205 is formed on a surface of the first tunneling dielectric layer 204a, and a second oxide layer 2061a is formed on a surface of the floating gate 205, wherein a first stack layer 301a is formed by a stack of the first tunneling dielectric layer 204a, the floating gate 205, and the second oxide layer 2061a; the first stack layer 301a also extends to a surface outside the first gate trench 203.

The material of the floating gate 205 includes a TiN layer.

The second oxide layer 2061a is an ALD oxide layer.

In the method according to the embodiment of the present application, the first tunneling dielectric layer 204a is an HTO oxide layer that is grown by means of an HTO process. A device for HTO process growth of the first tunneling dielectric layer 204a is a furnace with a temperature range of 600° C. to 900° C.

The TiN layer of the floating gate 205 is formed by means of deposition using a PVD process. A temperature of the PVD process for the TiN layer of the floating gate 205 is 400 degrees Celsius.
Step 32. Referring to FIG. 5E, the second oxide layer 2061a, the floating gate 205, and the first tunneling dielectric layer 204a are sequentially etched to form the first spacer structure 301 on the side surface of the first gate trench 203 in the self-aligned manner.

A second side surface of the first spacer structure 301 is formed by a stack of a second side surface of the second oxide layer 2061 and etched surfaces of the floating gate 205 and the first tunneling dielectric layer 204 at the bottom of the second side surface of the second oxide layer 2061; the bottom surface of the first gate trench 203 is exposed between the second side surfaces of the first spacer structure 301.
Step 4. Referring to FIG. 5F, a second spacer structure 302 is formed on the second side surface of the first spacer structure 301 in a self-aligned manner, including the following substeps:
Step 41. Referring to FIG. 5F, a third silicon nitride layer 2062a is formed on the second side surface of the first spacer structure 301 and on the bottom surface of the first gate trench 203, a fourth oxide layer 2063a is formed on a surface of the third silicon nitride layer 2062a, and a fifth silicon nitride layer 2064a is formed on a surface of the fourth oxide layer 2063a, wherein a second stack layer 302a is formed by a stack of the third silicon nitride layer 2062a, the fourth oxide layer 2063a, and the fifth silicon nitride layer 2064a. The second stack layer 302a also extends to a top surface of the first spacer structure 301 and a surface outside the first gate trench 203.

The fourth oxide layer 2063a is an HTO oxide layer.

The third silicon nitride layer 2062a serves as a protective layer for the floating gate 205 to prevent the TiN layer of the floating gate 205 from being oxidized.

In the method according to the embodiment of the present application, the third silicon nitride layer 2062a is an ALD silicon nitride layer that is grown by means of an ALD process; and the fifth silicon nitride layer 2064a is an ALD silicon nitride layer that is grown by means of an ALD process.
Step 42. Referring to FIG. 5G, the fifth silicon nitride layer 2064a, the fourth oxide layer 2063a, and the third silicon nitride layer 2062a are sequentially etched to form the second spacer structure 302 on the second side surface of the first spacer structure 301 in the self-aligned manner.

A second side surface of the second spacer structure 302 is formed by a stack of a second side surface of the fifth silicon nitride layer 2064 and etched surfaces of the fourth oxide layer 2063 and the third silicon nitride layer 2062 at the bottom of the second side surface of the fifth silicon nitride layer 2064; the bottom surface of the first gate trench 203 is exposed between the second side surfaces of the second spacer structure 302.
Step 5. Referring to FIG. 4, the first gate trench 203 between the second side surfaces of the second spacer structure 302 is filled with a control gate 207, the control gate 207 being in contact with the source region 202 at the bottom thereof.

After step 5, the method further includes:
referring to FIG. 4, an erase gate 213 and a second tunneling dielectric layer 213 between the erase gate 213 and the floating gate 205 are formed in a top region of the floating gate 205.

After forming a first side surface of the word line gate 208, the method further includes:

forming a drain region 211 in a surface region of the semiconductor substrate 201 on the first side surface of the word line gate 208 in a self-aligned manner.

In some embodiments, the following parameters may be adopted:

The thickness of the first tunneling dielectric layer 204a is 40 Å to 200 Å.

The thickness of the second oxide layer 2061a is 20 Å to 30 Å.

The thickness of the third silicon nitride layer 2062a is 20 Å to 30 Å.

The thickness of the fourth oxide layer 2063a is 20 Å to 100 Å.

The thickness of the fifth silicon nitride layer 2064a is 30 Å to 60 Å.

The thickness of the floating gate 205 is 20 Å to 40 Å.

In the method according to the embodiments of the present application, a non-storage region 304 is further provided outside the storage region 303. The non-storage region 304 includes a formation region of a source line strap (SL strap) or a formation region of a word line strap (WL strap).

Referring to FIG. 5A, at the same time when forming the first gate trench 203, the method in step 1 further includes forming a second gate trench 203a in the non-storage region 304, the second gate trench 203a being located above a field oxide 305, and the field oxide 305 being formed on the semiconductor substrate 201.

Referring to FIG. 5B, the first stack layer 301a is also formed on an inner side surface of the second gate trench 203a and on a surface outside the second gate trench 203a in step 31.

Before performing an etch process for the first spacer structure 301, the method in step 32 further includes:

referring to FIG. 5C, forming a first mask layer 306 for covering the storage region 303 and opening the non-storage region 304. In some embodiments, the first mask layer 306 is formed using a photoresist pattern, the photoresist pattern being obtained by means of a photolithographic process, i.e., obtained by exposing and developing a photoresist. In the photolithographic process for the first mask layer 306, the second oxide layer 2061a serves as a mask layer.

Referring to FIG. 5D, the entire first stack layer 301a in the non-storage region 304 is removed using the first mask layer 306 as a mask.

Referring to FIG. 5E, the first mask layer 306 is etched off.

In the method according to some embodiments, the etch of the second oxide layer 2061a in step 32 is anisotropic dry etch; a process of etching the TiN layer of the floating gate 205 in the first stack layer 301a is wet etch, and a wet etch solution is a mixed cleaning solution of HF, H₂O₂, and H₂O.

An etch process for the fifth silicon nitride layer 2064a, the fourth oxide layer 2063a, and the third silicon nitride layer 2062a in step 42 is an anisotropic dry etch process, and a high energy plasma is adopted in the anisotropic dry etch process.

The present application is described in detail above via specific embodiments, which, however, are not intended to limit the present application. Without departing from the principle of the present application, those skilled in the art can still make many variations and improvements, which should also be construed as the scope of protection of the present application.

What is claimed is:

1. A super flash, wherein a device cell is located in a storage region, and the device cell comprises:
a first gate trench formed at the top of a source region, with a bottom surface of the first gate trench being lower than a top surface of a semiconductor substrate and a top surface of the first gate trench being higher than a top surface of the semiconductor substrate;
the source region is formed in a surface region of the semiconductor substrate at the bottom of the first gate trench;
a first spacer structure is formed on a side surface of the first gate trench in a self-aligned manner, the first spacer structure is formed by means of self-aligned etch of a first stack layer, the first stack layer is formed by a stack of a first tunneling dielectric layer, a floating gate, and a second oxide layer, the first tunneling dielectric layer is formed on side and bottom surfaces of the first gate trench, the floating gate is formed on a surface of the first tunneling dielectric layer, and the second oxide layer is formed on a surface of the floating gate;
the material of the floating gate comprises a TiN layer;
a second side surface of the first spacer structure is formed by a stack of a second side surface of the second oxide layer and etched surfaces of the floating gate and the first tunneling dielectric layer at the bottom of the second side surface of the second oxide layer; the bottom surface of the first gate trench is exposed between the second side surfaces of the first spacer structure;
a second spacer structure is formed on the second side surface of the first spacer structure in a self-aligned manner, and the second spacer structure is formed by means of self-aligned etch of a second stack layer; the second stack layer is formed by a stack of a third silicon nitride layer, a fourth oxide layer, and a fifth silicon nitride layer; the third silicon nitride layer is formed on the second side surface of the first spacer structure and on the bottom surface of the first gate trench, the fourth oxide layer is formed on a surface of the third silicon nitride layer, and the fifth silicon nitride layer is formed on a surface of the fourth oxide layer;
the second side surface of the second spacer structure is formed by a stack of a second side surface of the fifth silicon nitride layer and etched surfaces of the fourth oxide layer and the third silicon nitride layer at the bottom of the second side surface of the fifth silicon nitride layer; the bottom surface of the first gate trench is exposed between the second side surfaces of the second spacer structure;
the second oxide layer is an ALD oxide layer;
the fourth oxide layer is an HTO oxide layer; and
the third silicon nitride layer serves as a protective layer for the floating gate to prevent the TiN layer of the floating gate from being oxidized.

2. The super flash according to claim 1, wherein a control gate fills the first gate trench between the second side surfaces of the second spacer structure, the control gate being in contact with the source region at the bottom thereof;
two word line gates are symmetrically disposed on the semiconductor substrate at both sides of the first gate trench, with each of the word line gates being isolated from the semiconductor substrate by a first gate dielectric layer therebetween;
the side surface of the first gate trench is isolated from a second side surface of the word line gate by a sixth dielectric layer therebetween;
an erase gate is formed in a top region of the floating gate, and the erase gate is spaced apart from the floating gate by a second tunneling dielectric layer therebetween; and
a drain region is formed in a surface region of the semiconductor substrate on a first side surface of the word line gate in a self-aligned manner.

3. The super flash according to claim 1, wherein the first tunneling dielectric layer is an HTO oxide layer.

4. The super flash according to claim 3, wherein the third silicon nitride layer is an ALD silicon nitride layer; and the fifth silicon nitride layer is an ALD silicon nitride layer.

5. The super flash according to claim 4, wherein the thickness of the first tunneling dielectric layer is 40 Å to 200 Å;
the thickness of the second oxide layer is 20 Å to 30 Å;
the thickness of the third silicon nitride layer is 20 Å to 30 Å;
the thickness of the fourth oxide layer is 20 Å to 100 Å; and
the thickness of the fifth silicon nitride layer is 30 Å to 60 Å.

6. The super flash according to claim 1, wherein the thickness of the floating gate is 20 Å to 40 Å.

7. A method for manufacturing a super flash, wherein a device cell is located in a storage region, and steps of forming the device cell comprise:
step 1, forming a first gate trench, the first gate trench being located at the top of a formation region of a source region, with a bottom surface of the first gate trench being lower than a top surface of a semiconductor substrate and a top surface of the first gate trench being higher than a top surface of the semiconductor substrate;
step 2, forming the source region in a surface region of the semiconductor substrate at the bottom of the first gate trench;
step 3, forming a first spacer structure on a side surface of the first gate trench in a self-aligned manner, comprising the following substeps:
step 31, forming a first tunneling dielectric layer on the side and bottom surfaces of the first gate trench, forming a floating gate on a surface of the first tunneling dielectric layer, and forming a second oxide layer on a surface of the floating gate, wherein a first stack layer is formed by a stack of the first tunneling dielectric layer, the floating gate, and the second oxide layer; the first stack layer also extends to a surface outside the first gate trench;
the material of the floating gate comprises a TiN layer;
the second oxide layer is an ALD oxide layer; and
step 32, sequentially etching the second oxide layer, the floating gate, and the first tunneling dielectric layer to form the first spacer structure on the side surface of the first gate trench in the self-aligned manner, wherein
a second side surface of the first spacer structure is formed by a stack of a second side surface of the second oxide layer and etched surfaces of the floating gate and the first tunneling dielectric layer at the bottom of the second side surface of the second oxide layer; the bottom surface of the first gate trench is exposed between the second side surfaces of the first spacer structure; and
step 4, forming a second spacer structure on the second side surface of the first spacer structure in a self-aligned manner, comprising the following substeps:
step 41, forming a third silicon nitride layer on the second side surface of the first spacer structure and on the bottom surface of the first gate trench, forming a fourth oxide layer on a surface of the third silicon nitride layer, and forming a fifth silicon nitride layer on a surface of the fourth oxide layer, wherein a second stack layer is formed by a stack of the third silicon nitride layer, the fourth oxide layer, and the fifth silicon nitride layer; the second stack layer also extends to a top surface of the first spacer structure and a surface outside the first gate trench;
the fourth oxide layer is an HTO oxide layer;
the third silicon nitride layer serves as a protective layer for the floating gate to prevent the TiN layer of the floating gate from being oxidized; and
step 42, sequentially etching the fifth silicon nitride layer, the fourth oxide layer, and the third silicon nitride layer to form the second spacer structure on the second side surface of the first spacer structure in the self-aligned manner, wherein
a second side surface of the second spacer structure is formed by a stack of a second side surface of the fifth silicon nitride layer and etched surfaces of the fourth oxide layer and the third silicon nitride layer at the bottom of the second side surface of the fifth silicon nitride layer; the bottom surface of the first gate trench is exposed between the second side surfaces of the second spacer structure.

8. The method for manufacturing a super flash according to claim 7, wherein two word line gates are symmetrically disposed on the semiconductor substrate at both sides of the first gate trench in step 1, with each of the word line gates being isolated from the semiconductor substrate by a first gate dielectric layer therebetween;
the side surface of the first gate trench is isolated from a second side surface of the word line gate by a sixth dielectric layer therebetween;
after step 4, the method further comprises: step 5, filling the first gate trench between the second side surfaces of the second spacer structure with a control gate, the control gate being in contact with the source region at the bottom thereof,
after step 5, the method further comprises:
forming an erase gate and a second tunneling dielectric layer between the erase gate and the floating gate in a top region of the floating gate;
after forming a first side surface of the word line gate, the method further comprises:
forming a drain region in a surface region of the semiconductor substrate on the first side surface of the word line gate in a self-aligned manner.

9. The method for manufacturing a super flash according to claim 7, wherein the first tunneling dielectric layer is an HTO oxide layer that is grown by means of an HTO process.

10. The method for manufacturing a super flash according to claim 9, wherein the third silicon nitride layer is an ALD silicon nitride layer that is grown by means of an ALD process; and the fifth silicon nitride layer is an ALD silicon nitride layer that is grown by means of an ALD process.

11. The method for manufacturing a super flash according to claim 10, wherein the thickness of the first tunneling dielectric layer is 40 Å to 200 Å;
the thickness of the second oxide layer is 20 Å to 30 Å;
the thickness of the third silicon nitride layer is 20 Å to 30 Å;
the thickness of the fourth oxide layer is 20 Å to 100 Å; and
the thickness of the fifth silicon nitride layer is 30 Å to 60 Å.

12. The method for manufacturing a super flash according to claim 9, wherein a temperature of the HTO process for the first tunneling dielectric layer is 600° C. to 900° C.

13. The method for manufacturing a super flash according to claim 7, wherein the TiN layer of the floating gate is formed by means of deposition using a PVD process.

14. The method for manufacturing a super flash according to claim 13, wherein a temperature of the PVD process for the TiN layer of the floating gate is 400 degrees Celsius.

15. The method for manufacturing a super flash according to claim 13, wherein the thickness of the floating gate is 20 Å to 40 Å.

16. The method for manufacturing a super flash according to claim 7, wherein a non-storage region is further provided outside the storage region;
at the same time when forming the first gate trench, the method in step 1 further comprises forming a second gate trench in the non-storage region, the second gate trench being located above a field oxide, and the field oxide being formed on the semiconductor substrate;
the first stack layer is also formed on an inner side surface of the second gate trench and on a surface outside the second gate trench in step 31;
before performing an etch process for the first spacer structure, the method in step 32 further comprises:
forming a first mask layer for covering the storage region and opening the non-storage region;
removing the entire first stack layer in the non-storage region using the first mask layer as a mask; and
etching off the first mask layer.

17. The method for manufacturing a super flash according to claim 7, wherein a process of etching the TiN layer of the floating gate in the first stack layer in step 32 is wet etch, and a wet etch solution is a mixed cleaning solution of HF, H₂O₂, and H₂O.

18. The method for manufacturing a super flash according to claim 7, wherein an etch process for the fifth silicon nitride layer, the fourth oxide layer, and the third silicon nitride layer in step 42 is an anisotropic dry etch process.
